(19) United States
(12) Patent Application Publication
(10) Pub. No.: US 2019/0310099 A1
(43) Pub. Date: Oct. 10, 2019

(54) OPERATING SYSTEM FOR A MOTOR VEHICLE, INTERIOR PART AND STEERING WHEEL WITH AN OPERATING SYSTEM

(71) Applicant: BCS AUTOMOTIVE INTERFACE SOLUTIONS GMBH, Radolfzell (DE)

(72) Inventors: HEINZ-JÖRG LEFRINGHAUSEN, Mainhausen (DE); VLADIMIR MENER, Elsenfeld (DE); NORBERT STAUDT, Aschaffenburg (DE); HANS-JÜRGEN BOSSLER, Münster (DE); VOLKER STEGMANN, Aschaffenburg (DE); KLAUS WEIGAND, Steinau a.d. Str. (DE)

(21) Appl. No.: 16/470,471

(22) PCT Filed: Nov. 9, 2017
(86) PCT No.: PCT/EP2017/078731

§ 371 Date: Jun. 17, 2019

(30) Foreign Application Priority Data
Dec. 16, 2016 (DE) 10 2016 014 979.5

(51) Int. Cl. G01C 21/36; H03K 17/96; G06F 3/0354

(52) U.S. Cl. CPC G01C 21/3652; H03K 17/96; G06F 2203/04105; H03K 2217/96062; G06F 3/03547

(57) ABSTRACT

An operating system for a motor vehicle has an operating surface with at least one operating area that is indicated by a symbol system on the operating surface, a touch sensor system by means of which a touch of the operating area is detectable, a drive for generating a haptic feedback by a movement of the operating surface, a drive frame which connects the drive to the operating surface in a force-transmitting manner, and an operating system carrier relative to which the operating surface is movable for generating the haptic feedback. An elastically pretensioned mounting is provided between the drive frame and the operating system carrier.

### RELATED APPLICATIONS

This application corresponds to PCT/EP2017/078731, filed Nov. 9, 2017, which claims the benefit of German Application No. 10 2016 014 979.5, filed Dec. 16, 2016, the subject matter of which are incorporated herein by reference in their entirety.

### BACKGROUND

The invention relates to an operating system for a motor vehicle for installation in the vehicle interior, as well as an interior part and a steering wheel with such an operating system. Using the operating system, a driver or vehicle occupant controls functions of the motor vehicle or sets default values for the systems of the motor vehicle. Modern operating systems are less and less frequently configured as electromechanical switch modules having clearly perceptibly movable keys, but as touch-sensitive systems that activate a vehicle function upon a touch, without the touched area of the system moving in a manner perceptible to the operator, as is known to operators of mobile phones or tablet computers equipped with touch panels.

A touch-sensitive operating system for a motor vehicle is disclosed in U.S. Pat. No. 8,169,306 B2. The known operating system includes an operating surface having a plurality of operating panels identified by symbols for controlling different vehicle functions. The operating surface is attached, by means of arms that are flexible in the direction of extent of the operating surface, to a base plate adapted to be fastened to the vehicle. A haptic drive is screwed to the operating surface and causes the operating surface to move parallel in relation to the base plate. In the known operating system, during operation of the haptic drive the operating panels reciprocate transversely to the line of sight of the operator, so that the symbols indicating the operating panels no longer appear sharply drawn to the operator. The sensation of the oscillating operating surface as perceived by the operator

### RELATED APPLICATIONS

This application corresponds to PCT/EP2017/078731, filed Nov. 9, 2017, which claims the benefit of German Application No. 10 2016 014 979.5, filed Dec. 16, 2016, the subject matter of which are incorporated herein by reference in their entirety.

The invention relates to an operating system for a motor vehicle for installation in the vehicle interior, as well as an interior part and a steering wheel with such an operating system. Using the operating system, a driver or vehicle occupant controls functions of the motor vehicle or sets default values for the systems of the motor vehicle. Modern operating systems are less and less frequently configured as electromechanical switch modules having clearly perceptibly movable keys, but as touch-sensitive systems that activate a vehicle function upon a touch, without the touched area of the system moving in a manner perceptible to the operator, as is known to operators of mobile phones or tablet computers equipped with touch panels.

A touch-sensitive operating system for a motor vehicle is disclosed in U.S. Pat. No. 8,169,306 B2. The known operating system includes an operating surface having a plurality of operating panels identified by symbols for controlling different vehicle functions. The operating surface is attached, by means of arms that are flexible in the direction of extent of the operating surface, to a base plate adapted to be fastened to the vehicle. A haptic drive is screwed to the operating surface and causes the operating surface to move parallel in relation to the base plate. In the known operating system, during operation of the haptic drive the operating panels reciprocate transversely to the line of sight of the operator, so that the symbols indicating the operating panels no longer appear sharply drawn to the operator. The sensation of the oscillating operating surface as perceived by the operator does not meet the expectations of operators, who are frequently still used to electromechanical switching elements, for a confirmation that the desired vehicle function has been activated. The acoustically perceivable vibration or humming noise generated by the oscillating operating surface is sometimes perceived as disturbing. Finally, a triggering of vehicle functions by merely touching an operating surface is conducive to distracting the operator from traffic since an inadvertent touching can easily occur.

### SUMMARY OF THE INVENTION

It is the object of the invention to overcome the drawbacks of the prior art, in particular to provide an operating system for a motor vehicle, an interior part and a steering wheel having an operating system which meet high aesthetic, ergonomic and haptic requirements and are cost-effective to manufacture.

This object is achieved by the subject matters of the independent claims.

According to a first aspect of the invention, an operating system for a motor vehicle includes an operating surface having at least one operating area that is indicated by a symbol system on the operating surface, a touch sensor system by means of which a touch of the operating area is detectable, a drive for generating a haptic feedback by a movement of the operating surface, a drive frame which connects the drive to the operating surface in a force-transmitting manner, and an operating system carrier relative to which the operating surface is movable for generating the haptic feedback. According to the invention, an elastically pretensioned mounting is provided between the drive frame and the operating system carrier. The pretension allows a positioning of the components relative to each other to be achieved with minimum or, if possible, no play, which results in a monolithic, higher-quality appearance. Applying the pretension furthermore limits movements contrary to the direction of pretension. The elastically pretensioned mounting thus does not linearly cushion and dampen the movements of the drive in relation to the operating system carrier mounted to the vehicle. The resulting haptic feedback is perceived as a rich pulse and as being of high quality.

In a further development of the invention, the elastically pretensioned mounting limits a movement of the drive frame contrary to the actuating direction of the operating surface. In this way, an acceleration—frequently perceived as being unpleasant—of the operating system towards the operator's finger in response to the contact pressure is reduced. In particular, the movement of the operating surface contrary to the direction of actuation is limited, preferably to the neutral position in the pretensioned state.

In a further development of the invention, the drive frame is mounted at the operating system carrier so as to be pivotable with respect to at least two axes. The drive frame itself is of rigid configuration, based on the operating forces usually acting on operating systems, including a safety margin. In particular, the swivel axes are defined by the clamping points of the drive holder on the operating system carrier. In particular, a pivoting about one of the at least two axes increases the tension of the elastically pretensioned mounting. The increase in the tension applied to the elastic mounting can be evaluated by means of a sensor system and made use of for making the touch sensor system plausible.

In a further development of the invention, the elastically pretensioned mounting includes at least one spring element pre-compressed between the drive frame and the operating system carrier. In particular, the spring element is configured to be electrically conductive and/or as a sensor of an actuation sensor system. Preferably, a plurality of spring elements or a plurality of parts of the elastically pretensioned mounting are in the form of sensors and connected to an evaluation electronics of the operating system. In particular, the elastic mounting includes a plurality of spring elements mechanically connected in series or parallel. In particular, not all spring elements are electrically conductive. In particular, at least two, preferably exactly four, electrically conductive spring elements are provided. This allows a low-displacement swiveling movement of the drive frame to be cushioned and/or an actuating force applied to the operating surface and its location to be precisely determined and/or made plausible.

According to a further aspect of the invention, an operating system for a motor vehicle includes an operating surface having a plurality of operating areas indicated by a symbol system on the operating surface, a light source which is common to the operating areas and operatively illuminates the symbol system, a touch sensor system which operatively detects a touch of the operating surface in at least one of the operating areas, an actuation sensor system which detects an actuating force acting on the operating surface, and a drive for generating a haptic feedback by a movement of the operating surface. A respective operating area is provided for controlling a specific function of the motor vehicle or setting a default value for motor vehicle system. The light source common to the operating areas assumes a lighting function for a symbol system which has a display function for a respective one of the operating areas. In particular, the symbol system displays the respective operating areas or separates them from each other. Preferably, the symbol system comprises a plurality of symbols or parts of a graphic representation that are backlit by the shared light source. In particular, the symbol system comprises a respective function-specific symbol for one or more functional areas of the operating surface. In a special configuration, the symbol system comprises a backlit line illustration that separates one functional area from another functional area and thus displays a plurality of functional areas.

In a further development of the invention, the common light source backlights a predominant part, in particular backlights at least 50%, preferably at least 80% or 90%, of the operating surface. In particular, the light source includes fewer electric lamps than the symbol system includes separately illuminated symbols. In particular, the operating system includes fewer light sources than illuminated symbols, the illumination of the symbols being homogeneous. In addition to a reduction in lamps and costs, the large-area backlighting of the operating surface allows the operating areas and the symbol system to be freely configurable. An adaptation to different equipment variants is thus possible on the basis of one single basic operating system with reduced modification effort.

In a further development of the invention, the actuation sensor system detects, in a spatially resolved manner, an actuating force acting on the operating surface. To this end, a plurality of actuation sensors are provided which, preferably in a triangulation process, in particular taking into account the geometry of the drive frame, determine the location on the operating surface to which the actuating or operating force is applied. More particularly, an evaluation electronics or a microcontroller evaluates the signals of the actuation sensor system. In one variant, the microcontroller also evaluates the time course of the forces sensed by the actuation sensors.

In a further development of the invention, the operating system generates a haptic feedback independently of the touch sensor system or the actuation sensor system, in particular, the operating system comprises a communication interface, in particular a LIN BUS interface, via which a release command for the haptic feedback is communicated to the operating system.

In a further development of the invention, the actuation sensor system senses the release force continuously over time. In particular, the invention comprises a microcontroller that continuously evaluates signals of the actuation sensor system.

In a further development of the invention, an actuating force threshold for the activation of a vehicle function is freely programmable. In particular, the threshold is programmed parametrically, that is, as a function of other vehicle parameters, in a time-dependent manner and/or in a position-dependent manner with respect to the operating surface.

In a further development of the invention, the microcontroller makes plausible a touching of the operating surface detected by the touch sensor system, in particular with regard to its presence and/or its location, with the aid of the actuating force sensed, in particular a plurality of actuating forces sensed, by the actuation sensor system, preferably in a triangulation process. At least in a further development, the making plausible increases the Automotive Safety integrity Level (ASIL) and the functional safety of the operating system.

In a further development of the invention, the actuation sensor system determines an actuating force applied to the operating surface from an increase in the tension of the elastically pretensioned mounting.

In a further development of the invention, the actuation sensor system comprises a maximum of n sensors for determining the position of an actuating force with respect to at least n+2 operating areas. In this particular embodiment, the number n is greater than two. In particular, the actuation sensor system comprises an evaluation electronics, in particular a microcontroller, which determines the operating area that is acted upon by the actuating force as a function of measured value combinations of the n sensors.

In a further development of the invention, a microcontroller evaluates the touch sensor system in order to determine and/or make plausible the distribution of the forces on the operating surface as measured by means of the actuation sensor system.

In a further development of the invention, the operating surface does not move in relation to the operating system carrier such as to be perceptible to an operator up to a multiple of a predetermined actuating force in the operating direction. In particular, the movement travel amounts to less than 0.5 millimeters, preferably less than 0.2 millimeters. Preferably, the operating surface and/or the drive frame supporting the operating surface is reinforced in particular with a truss structure and/or is formed from a rigid or inelastic material, such as glass, so that no deformation of the operating surface is perceptible when it is actuated. Preferably, all operating areas of the operating surface are integrated in a seamless and/or jointless decorative surface or the operating surface forms such a surface.

In a further development, the haptic feedback comprises a movement of the operating surface in the direction of the elastic pretension. At least one variant of the invention ensures a low-travel actuation of a vehicle function, in particular one that is not perceptible and/or only measurable.

The invention also relates to an interior part that comprises a decorative interior surface and an operating system according to the invention, the operating surface of the operating system constituting part of the interior surface. The group of interior parts in which the operating system can be employed includes center consoles, dashboards, rear seats, door linings or any desired interior lining parts, such as trunk linings.

In a further development of the invention, the operating surface and/or the light source comprises an optical filter which makes the symbol system visually indistinguishable to the operator from the rest of the operating surface or interior surface when the common light source is out of operation.

Finally, the invention also relates to a steering wheel having an operating system according to the invention.

### BRIEF DESCRIPTION OF THE DRAWINGS

Further characteristics, advantages and features of the invention will be explained by the following description of preferred embodiments by reference to the accompanying drawings, in which:

FIG. 1 shows a schematic sectional representation of a first embodiment of an operating system according to the invention;

FIG. 2 shows a schematic sectional representation of a second embodiment of an operating system according to the invention;

FIG. 3 shows a perspective exploded representation of a third embodiment of an operating system according to the invention;

FIG. 4a shows a schematic top view of a light source of an operating system according to the invention;

FIG. 4b shows a schematic sectional representation taken through a light source of an operating system according to the invention.

### DESCRIPTION

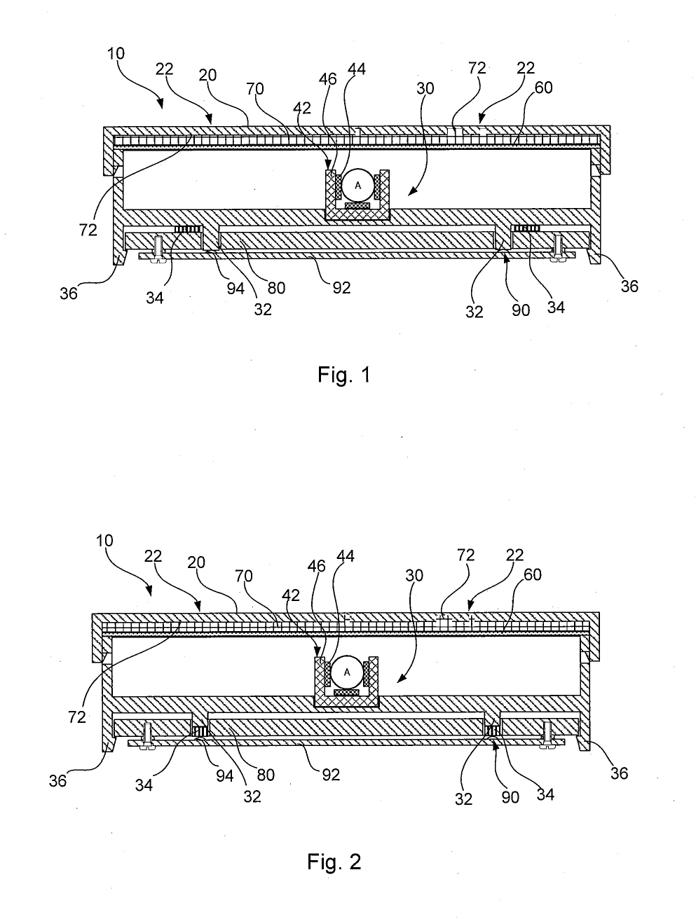

FIG. 1 shows a schematic cross section taken through an operating system according to the invention. The operating system 10 is mounted on a torsion-resistant operating system carrier 80, which is connected to a component of a motor vehicle via attachment points that are not illustrated in greater detail. An electrical circuit board 92 is rigidly fastened to the operating system carrier 80. The electrical circuit board 92 has an electrical circuit provided thereon for controlling a drive 40 as well as a light source 70 of the operating system 10, evaluation of a sensor system, in particular a touch sensor system 60, and communication with other systems of the motor vehicle. In particular, the electrical circuit comprises an evaluation electronics. The operating system carrier 80 has two diametrically opposed passages 82 which connect the side facing the operator with the circuit board side. Two disk springs 94 are arranged on the circuit board 92, each concentrically to a respective passage 82. In a preferred variant, the disk springs 94 are electrically conductive and part of a capacitive actuation sensor system 90. In particular, the disk springs 94 are metallic or made from an electrically conductive plastic material. In particular, the disk springs 94 move relative to electrical conductor tracks applied to the circuit board and thereby change an electric field generated between a respective disk spring 94 and a section of the conductor tracks.

A drive frame 30 carrying the drive 40 is mounted in a guided manner at the operating system carrier 80. To this end, guide tappets 32 integrally molded with the drive frame 30 extend through the passages 82 in the operating system carrier 80. In particular, the guide tappets 32 are formed to be complementary in shape and/or to have a small play, in particular less than 0.5 mm, preferably less than 0.2 mm, with respect to the respective passage 82. The guide tappets 32 are dimensioned such that the disk springs 94 are elastically pre-compressed in the non-actuated assembly state of the operating system 10.

The drive frame 30 is furthermore supported relative to the operating system carrier 80 on two spring elements 34. Holding arms 36 extend from the drive frame toward the operating system carrier 80. The holding arms 36 are arranged at the drive frame 30 diametrically opposite each other, particularly with respect to a geometric center of the operating system, and engage with the operating system carrier 80 in a form-fitting manner. The holding arms 36 are rigid, in particular with regard to the forces acting on the operating system 10 by the drive 40. The holding arms 36 are dimensioned and arranged at the drive frame 30 such that the spring elements 34 are elastically compressed between the drive frame 30 and the operating system carrier 80 in the non-actuated assembly state of the operating system 10. Any movement of the drive frame 30 relative to the operating system carrier 80 that does not occur in the actuation direction is blocked by the holding arms 36. The holding arms 36 are configured with little play, in particular less than 0.5 mm, preferably less than 0.2 mm, in relation to the operating system carrier 80 transverse to the compression direction of the spring elements 34 in order to permit a slight swiveling movement of the drive frame 30 relative to the operating system carrier 80. The swivel axes are defined by the points of engagement of the holding arms 36 on the operating system carrier 80.

The drive frame 30 comprises a seat for a drive holder 42 which can be modularly connected to the drive frame 30. In particular, the drive holder 42 engages around the drive 40 from at least three sides. The drive holder 42 is preferably in the form of a 2-component injection molded part which comprises a dimensionally stable hard component 44 that is preferably rigid with respect to the drive forces, and an elastically damping soft component 46, such as an elastomer or silicone-containing material. Preferably, the drive holder 42 is formed as a C-shaped clamp, the drive 40 being enclosed in the soft component by frictional engagement between the legs of the clamp.

The operating system 10 comprises an operating surface 20 which is supported on the drive frame 30. In the operating condition, an illuminated symbol system is visible on the operating surface 20, displaying at least one operating area 22 to the operator. The symbol system consists of one or more symbols. A light source 70 is arranged on the side of the operating surface 20 facing away from the operator. A symbol may be formed by an opening 72 in a shadow mask optically separating the light source 70 from the operating surface 20 so that the light source shines through the symbol. A layer with an optical effect, such as a polarization filter, may furthermore be provided between the shadow mask and the operating surface 20, making the opening 72 in the shadow mask 74 invisible to an operator when the light source 70 is out of operation.

The operating surface 20 is preferably configured to be dimensionally stable and non-deformable with respect to the usual actuating forces, such as, e.g., smaller than or equal to 50 Newtons. In particular, the operating surface 20 is formed of a plastic material or glass provided with a decorative layer. Arranged behind the operating surface 20 is a touch sensor system 60, which detects a touch of the operating surface 20 in one of the operating areas 22. The touch sensor system 60 is, for example, a capacitive sensor film. In particular, the touch sensor system 60 and/or the light source 70 extend(s) over at least 50%, preferably at least 80%, preferably at least 95%, of the visible operating surface 20.

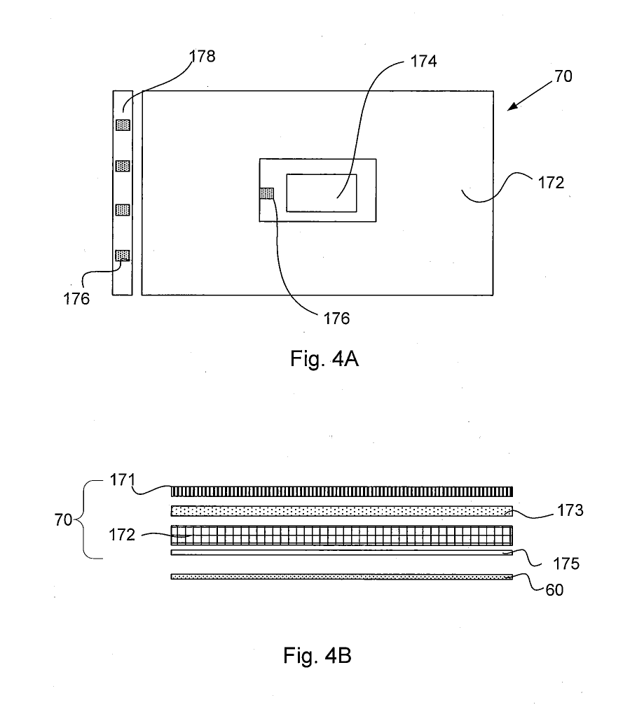

The light source 70 is schematically illustrated in detail in FIGS. 4A and 4B. The light source 70 comprises an LED strip 178 with a plurality of LEDs 176 as the main illuminant. An area light guide 172 extends away from the main illuminant on one side, preferably along the entire operating area 20. A recess is provided in a central region of the area light guide 172 remote from the main illuminant. Inserted in the recess is a further light guide 174 which is supplied with a luminous flux by an LED 176.

As illustrated in FIG. 4B, a mirror film 175 is arranged on the side of the area light guide 172 facing away from the operator. The mirror film 175 extends over the entire area light guide 172 including the region of the recess in which the further light guide 174 is arranged. Adjoining it on the side facing the operator is an optical diffusion agent 173 that is covered by a polarization filter 171. Using these measures, a completely homogeneous illumination is achieved over the entire area covered by the area light guide. On the side of the light source 70 facing away from the operator, the touch sensor system 60 is arranged, preferably in the form of a capacitive sensor matrix. Preferably, the touch sensor system 60 and the light source 70 constitute a module which is connected to the electrical circuit of the operating system 10 by a flexible cable 73. The arrangement shown in FIGS. 4A and 4B allows a homogeneously radiating light source 70 to be provided over the entire operating surface 20, using a comparatively small number of illuminants.

The embodiment shown in FIG. 2 of an operating system according to the invention corresponds almost entirely to the operating system 10 of FIG. 1. Insofar, all of the remarks made regarding FIG. 1 and the operating system 10 apply equally to the operating system of FIG. 2. The only difference between the operating systems 10 of FIGS. 1 and 2 consists in the elastically pretensioned mounting. In FIG. 2, the spring elements 34 and the disk springs 94 are arranged mechanically in series to produce the elastically pretensioned mounting. In contrast, in the operating system 10 of FIG. 1, the spring elements 34 and the disk springs 94 are arranged mechanically parallel.

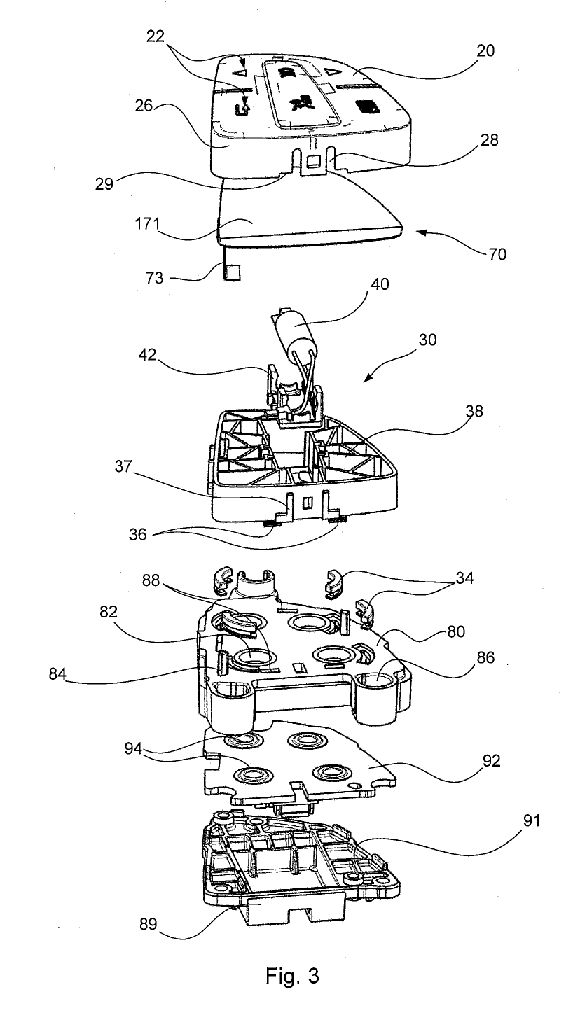

FIG. 3 shows a further exemplary embodiment of an operating system 10 according to the invention, the components corresponding to FIGS. 1 and 2 being provided with the same reference numbers. The operating system 10 shown in FIG. 3 is designed as a multifunctional operating unit that can be integrated into a steering wheel. The operating surface 20 comprises six operating areas 22, each of which is displayed by an illuminated symbol. The operating surface 20 is part of a cover 26 which covers the drive frame 30. The light source 70 is arranged between the operating surface 20 and the drive frame 30. Together with the drive frame 30, the cover 26 forms a housing for the drive 40, in which the light source 70 is encapsulated, in particular so as to be light-tight. The housing constitutes a rigid total mass which is set in motion by the drive 40 to generate a haptic feedback.

The cover 26 is latched to the drive frame 30 by means of a linear guide, such as an elongated hole 28 which includes a pretension stop 29 in the direction of actuation, at the drive frame 30. Arranged on the outer wall of the drive frame 30 are guide rails 37, into which the linear guide engages with a precise fit. The linear guide ensures that the operating surface 20 experiences a direct force transmission from and to the drive frame 30 without generating any acoustically disturbing noises.

The drive frame 30 is designed with a truss structure 38 inside its outer wall. The truss structure 38 defines a central recess in which the drive holder 42 is received with an interlocking fit. Extending from the side of the drive frame 30 facing away from the operator are the guide tappets 32, which are not illustrated for reasons of perspective, and holding arms 36 towards the operating system carrier 80.

The operating system carrier 80, together with the bottom 89, forms a lower housing. The circuit board 92 with the electrical circuit of the operating system and the disk springs 94 is bolted to the operating system carrier 80 and the bottom 89. The bottom 89 has a multitude of reinforcing struts 91 which constitute a rigid support for the disk springs 94, which is non-deformable with respect to the actuating forces. The operating system carrier 80 has three attachment points 86, which can be fixed on the vehicle side. The operating system carrier 80 is pierced by four circular passages 82 in which the guide tappets 32 of the drive carrier are accommodated. The holding arms 36 of the drive frame 30 engage in a form-fitting manner in dedicated recesses 88 of the operating system carrier 80, Provided concentrically with each of the passages 82 is a respective circular ring segment shaped spring element 34. When the drive frame 30 is mounted to the operating system carrier 80, the spring elements 34 are compressed between the outer surface of the drive frame 30 facing the operating system carrier 80 and the operating system carrier 80. The holding arms 36 maintain the pretensioning force in the assembled condition. When the bottom 89 is bolted to the operating system carrier 80, the disk springs 94 at the ends of the guide tappets 32 facing the circuit board are also pre-compressed. In this case, the pretension is maintained by the bolted connection between the bottom 89 and the operating system carrier 80. For a simpler and process-safe assembly, the operating system carrier 80 includes two positioning pins 84, which engage in dedicated retainers in the drive frame 30.

The touch sensor system 60 operatively provides a signal that contains information about the position coordinates of the touched point on the operating surface 20. For example, the touch sensor system 60 may be in the form of a capacitive film with a matrix structure. The electrical circuit of the operating system includes at least one microcontroller for evaluating the signals of the touch sensor system 60. An allocation table between signal values of the touch sensor system 60 and the operating areas 22 of the operating surface 20 is stored, for example, in a memory of the microcontroller. In a special embodiment, the touch sensor system 60 is designed such that it already detects an approach to the touch sensor system at a distance in a range of equal to or smaller than 10 mm.

To avoid an unintentional activation of a vehicle function, the microcontroller monitors the actuation sensor system 90 formed by the disk springs 94 simultaneously over time with regard to the force applied to the respectively touched operating area 22 and/or the entire operating surface 20, In particular, the microcontroller evaluates the signals of the touch sensor system in terms of how much of the operating surface 20 is touched, in order to determine an actuating pressure. The microcontroller activates the vehicle function if a force threshold value in the relevant operating area 22 is exceeded. Owing to the continuous monitoring of the force signal, the microcontroller, in a special variant, realizes different vehicle functions depending on the force applied. For example, a light actuating pressure will increase the preset speed of a cruise control system by 1 km/h each time, whereas a higher actuating pressure will cause it to be increased by 5 km/h each time.

Depending on whether a threshold value for the force applied is exceeded and/or a vehicle function is activated, upon a command of the microcontroller, the electrical circuit triggers a haptic feedback by the drive 40. Additionally or alternatively, a request for a haptic feedback may be communicated to the microcontroller via a communication interface. To generate the haptic feedback, the drive 40 receives an electrical pulse from the electrical circuit, in particular a driver module. The electrical pulse causes a movement of the drive and thus a movement of the drive frame 30 and of the operating surface 20 that is connected to the drive frame 30 in a force transmitting manner, in the embodiment illustrated, the drive 40 is an unbalance motor that is driven to perform a partial revolution. The pulse excitation and partial revolution prevent the operating surface 20 from vibrating unpleasantly. Rather, the haptic feedback conveys the sensation of a mechanical activation.

The features disclosed in the foregoing description, the figures and claims may be of significance, both individually and in any desired combination, to the implementation of the invention in its various configurations.

1: An operating system (10) for a motor vehicle, comprising: an operating surface (20) having at least one operating area (22) that is indicated by a symbol system on the operating surface (20), a touch sensor system (60) by means of which a touch of the operating area (22) is detectable, a drive (40) for generating a haptic feedback by a movement of the operating surface (20), a drive frame (30) which connects the drive (40) to the operating surface (20) in a force-transmitting manner, and an operating system carrier (80) relative to which the operating surface (20) is movable for generating the haptic feedback, wherein an elastically pretensioned mounting between the drive frame (30) and the operating system carrier (80).

2: The operating system (10) according to claim 1, wherein the elastically pretensioned mounting limits a movement of the drive frame (30) contrary to the actuating direction of the operating surface (20).

3: The operating system (10) according to claim 1 wherein the drive frame (30) is mounted at the operating system carrier (80) so as to be pivotable with respect to at least two axes, wherein in particular a pivoting about one of the at least two axes increases the tension of the elastically pretensioned mounting.

4: The operating system (10) according to claim 1, wherein the elastic pretensioned mounting includes at least one spring element pre-compressed between the drive frame (30) and the operating system carrier (80), wherein in particular the spring element is configured to be electrically conductive and/or as a sensor of an actuation sensor system (90).

5: An operating system (10) for a motor vehicle in according to claim 1, comprising: an operating surface (20) having a plurality of operating areas (22) indicated by a symbol system (24) on the operating surface, a light source (70) common to the operating areas (22) for illuminating the symbol system,
a touch sensor system (60) which operatively detects a touch of the operating surface (20) in at least one of the operating areas (22), an actuation sensor system (90) which detects an actuating force acting on the operating surface (20), and a drive (40) for generating a haptic feedback by a movement of the operating surface (20).

6: The operating system (10) according to claim 1, wherein the drive (40) is an unbalance motor driven in particular by means of an electrical pulse, wherein in particular the unbalance motor is driven in such a way for generating the haptic feedback that the unbalanced mass experiences less than 5, in particular less than 2, preferably less than 1, or only a partial revolution with respect to its original position.

7: The operating system (10) according to claim 1, wherein the common light source (70) backlights a predominant part of the operating surface (20) and/or includes fewer electric lamps than the symbol system includes separately illuminated symbols.

8: The operating system (10) according to claim 1, wherein the actuation sensor system (90) detects, in a spatially resolved manner, an actuating force acting on the operating surface (20) and/or the drive (40) generates a haptic feedback independently of the touch sensor system (60) or the actuation sensor system (90).

9: The operating system (10) according to claim 1, wherein the actuation sensor system (90) determines an actuating force on the operating surface (20) from an increase in the tension of the elastically pretensioned mounting and/or in that a microcontroller makes plausible, with the aid of the actuating force detected by the actuation sensor system (90), a touch of the operating surface (20) detected by the touch sensor system (60).

10: The operating system (10) according to claim 1, wherein the actuation sensor system (90) includes a maximum of n sensors for determining the position of an actuating force with respect to at least n+2 operating areas (22), wherein in particular the actuation sensor system comprises an evaluation electronics which determines the operating area (22) that is acted upon by the actuating force as a function of measured value combinations of the n sensors.

11: The operating system (10) according to claim 1, wherein the operating surface (20) does not move in relation to the operating system carrier (80) such as to be perceptible to an operator up to a multiple of a predetermined actuating force in the operating direction, in particular moves 0.5 millimeters or less, preferably 0.2 millimeters or less, and/or no deformation of the operating surface (20) is perceptible.

12: The operating system (10) according to claim 1, wherein the haptic feedback comprises a movement of the operating surface (20) in the direction of the elastic pretension.

13: An interior part for a motor vehicle, comprising a decorative interior surface and an operating system (10) configured according to claim 1, wherein part of the interior surface constitutes the operating surface (20), wherein in particular the operating surface (20) includes an optical filter which the symbol system visually indistinguishable from the remaining interior surface the common light source (70) is out of operation.

14: A steering wheel for a motor vehicle, including an operating system (10) according to claim 1.
